(19) United States
(12) Patent Application Publication
(10) Pub. No.: US 2026/0022455 A1
(43) Pub. Date: Jan. 22, 2026

(54) FILM FORMING METHOD AND FILM FORMING APPARATUS

(71) Applicant: Tokyo Electron Limited, Tokyo (JP)

(72) Inventor: Yusuke IGUCHI, Yamanashi (JP)

(21) Appl. No.: 19/259,612

(22) Filed: Jul. 3, 2025

(30) Foreign Application Priority Data
Jul. 17, 2024 (JP) 2024-114028

(51) Int. Cl. C23C 16/42; C23C 16/04

(52) U.S. Cl. CPC C23C 16/42; C23C 16/045

(57) ABSTRACT

A metal-containing film forming method includes preparing a substrate having a semiconductor region containing silicon and an insulator region on a surface of the substrate, and forming a first film containing a first metal on the surface of the substrate by simultaneously supplying a raw material gas containing the first metal and an etching gas for etching the first film to the substrate.

### CROSS-REFERENCE TO RELATED APPLICATIONS

Priority is claimed to Japanese Patent Application No. 2024-114028, filed Jul. 17, 2024, the entire content of which is incorporated herein by reference.

### BACKGROUND

### 1. Technical Field

The present disclosure relates to a film forming method and a film forming apparatus.

### 2. Description of Related Art

Japanese Unexamined Patent Application Publication No. H11(1999)-61415 (hereinafter “Patent Document 1”) discloses a technique for controlling film formation conditions so as to maintain an optimum emission intensity by monitoring the emission intensities of film formation species and etching species contained in plasma in film formation using a plasma chemical vapor deposition (CVD) method in which a film deposition reaction and an etching reaction occur simultaneously. Japanese Unexamined Patent Application Publication No. 2014-179393 (hereinafter “Patent Document 2”) discloses a technique of selectively etching a TiN film at the bottom of a contact hole by using a gas containing chlorine atoms, fluorine atoms, and carbon atoms.

### SUMMARY

A metal-containing film forming method according to an aspect of the present disclosure includes preparing a substrate having a semiconductor region containing silicon and an insulator region on a surface of the substrate, and forming a first film containing a first metal on the surface of the substrate by simultaneously supplying a raw material gas containing the first metal and an etching gas for etching the first film to the substrate.

### BRIEF DESCRIPTION OF THE DRAWINGS

FIG. 1 is a flowchart illustrating a film forming method according to a first embodiment;

FIGS. 2A, 2B, 2C, and 2D are cross-sectional views illustrating the film forming method according to the first embodiment;

FIG. 3 is a timing chart illustrating a first example of step S16 in FIG. 1;

FIG. 4 is a timing chart illustrating a second example of step S16 in FIG. 1;

FIG. 5 is a flowchart illustrating a film forming method according to a second embodiment;

FIG. 6 is a timing chart illustrating an example of step S27 in FIG. 5;

FIG. 7 is a diagram illustrating a processing system according to an embodiment;

FIG. 8 is a cross-sectional view illustrating a film forming apparatus according to an embodiment; and

FIG. 9 is a diagram illustrating results of measuring a thickness of a zirconium film.

### DETAILED DESCRIPTION

According to the present disclosure, a metal film thicker in a semiconductor region than in an insulator region can be formed.

Non-limiting exemplary embodiments of the present disclosure will be described below with reference to the accompanying drawings. In all the accompanying drawings, the same or corresponding members or parts are denoted by the same or corresponding reference numerals, and redundant description will be omitted.

### <Film Forming Method>

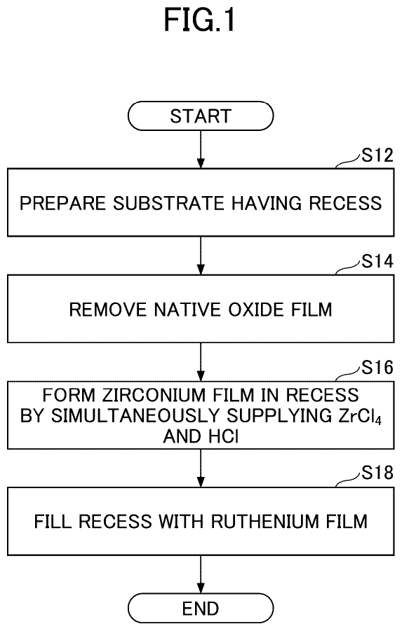

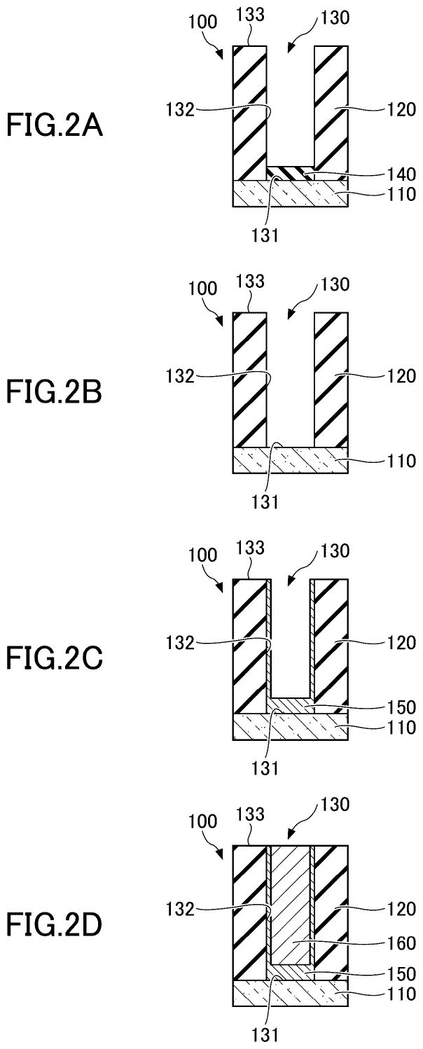

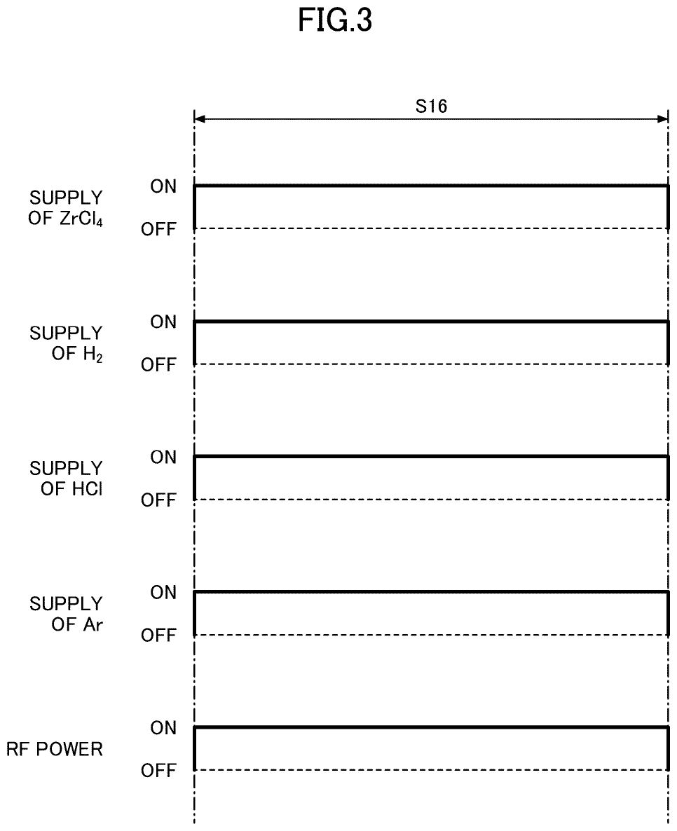

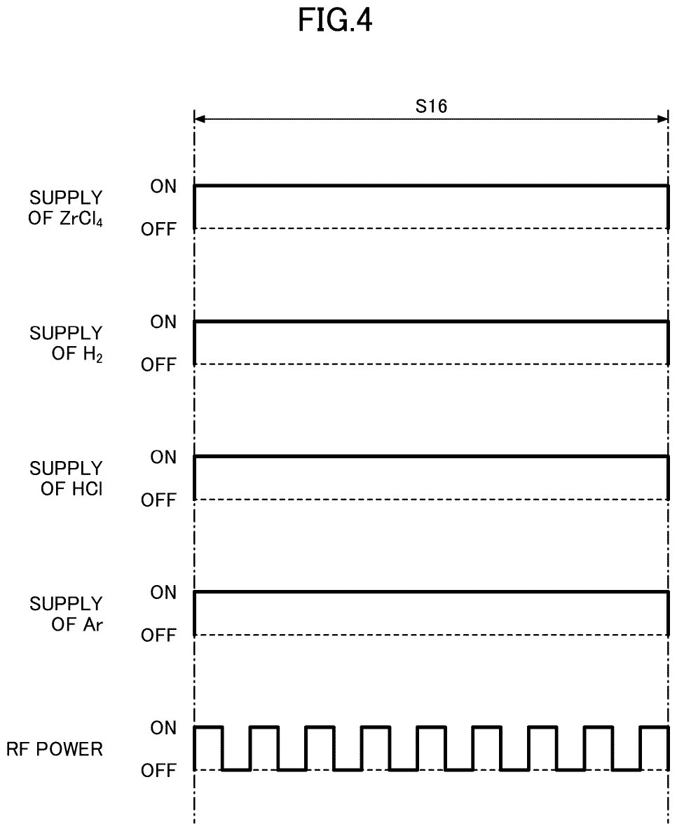

A film forming method according to the first embodiment will be described with reference to FIGS. 1 through 4. FIG. 1 is a flowchart illustrating the film forming method according to the first embodiment. FIGS. 2A through 2D are cross-sectional views illustrating the film forming method according to the first embodiment. FIG. 3 is a timing chart illustrating a first example of step S16 in FIG. 1. FIG. 4 is a timing chart illustrating a second example of step S16 in FIG. 1. The film forming method according to the first embodiment includes step S12, step S14, step S16, and step S18 illustrated in FIG. 1.

Step S12 includes preparing a substrate 100, as illustrated in FIG. 2A. The substrate 100 includes a silicon substrate 110 and a silicon nitride film 120. The silicon substrate 110 is an example of a semiconductor region containing silicon (Si). The silicon nitride film 120 is provided on the silicon substrate 110. The silicon nitride film 120 is, for example, an interlayer insulating film. The silicon nitride film 120 is an example of an insulator region. A recess 130 is formed in the silicon nitride film 120. The recess 130 is a contact hole, for example. The recess 130 has a bottom surface 131, a side surface 132, and an upper surface 133. The silicon substrate 110 forms the bottom surface 131. The silicon nitride film 120 forms the side surface 132 and the upper surface 133. A native oxide film 140 may be formed on the bottom surface 131.

Step S14 includes removing the native oxide film 140 as illustrated in FIG. 2B. Step S14 includes, for example, a chemical oxide removal (COR) process and a post heat treatment (PHT) process. The COR process is a process of supplying a gas containing a halogen element and a basic gas as a processing gas to the substrate 100 to cause a chemical reaction between the native oxide film 140 on the surfaces of the recess 130 and the processing gas, thereby generating a reaction product. The gas containing a halogen element is, for example, hydrogen fluoride (HF). The basic gas is, for example, ammonia (NH₃). In this case, a product containing ammonium fluorosilicate [(NH₄)₂SiF₆] or water (H₂O) is mainly produced. The PHT process is a process of heating the reaction product generated by the COR process to sublimate the reaction product, such as ammonium fluorosilicate. Step S14 is not limited to the process including the COR process and the PHT process. For example, step S14 need not include the PHT process. In the case where the native oxide film 140 is not present on the surfaces of the recess 130, step S14 may be omitted.

As illustrated in FIG. 2C, step S16 includes forming a zirconium film 150 on the surfaces of the recess 130 by simultaneously supplying zirconium chloride (ZrCl₄), hydrogen (H₂), and hydrogen chloride (HCl) to the substrate 100. Zirconium (Zr) is an example of a first metal, and the zirconium film is an example of a first film. Zirconium chloride is an example of a raw material gas, and hydrogen chloride is an example of an etching gas. When zirconium chloride and hydrogen are supplied to the substrate 100, the zirconium film 150 is formed on the bottom surface 131, the side surface 132, and the upper surface 133 of the recess 130. At this time, since the bottom surface 131 is formed by the silicon substrate 110, a part of the zirconium film and silicon of the silicon substrate 110 forming the bottom surface 131 react with each other on the bottom surface 131, and zirconium silicide (ZrSi) is formed. The zirconium silicide reduces the contact resistance between the silicon substrate 110 and a ruthenium film 160, which is described later. Since the side surface 132 and the upper surface 133 are formed of the silicon nitride film 120, zirconium silicide is not formed on the side surface 132 and the upper surface 133. Zirconium silicide is an example of a metal silicide. In this specification, zirconium silicide is included among the zirconium films 150. Hydrogen chloride etches the zirconium film 150 and does not appreciably etch zirconium silicide. Therefore, when hydrogen chloride is supplied to the substrate 100, the zirconium film 150 formed on the bottom surface 131 is not appreciably etched, and the zirconium film 150 formed on the side surface 132 and the upper surface 133 is etched. As a result, the zirconium film 150 can be formed on the bottom surface 131 of the recess 130 to be thicker than on the side surface 132 and the upper surface 133. When the zirconium film 150 having a desired thickness is formed on the bottom surface 131 of the recess 130, step S16 is completed.

Step S16 may include generating a plasma from zirconium chloride, hydrogen, and hydrogen chloride. In this case, the reduction of zirconium chloride by hydrogen proceeds, and the formation of the zirconium film 150 can be facilitated. An RF power supply may be used to generate plasma. Step S16 may include providing an inert gas such as argon. As illustrated in FIG. 3, in step S16, zirconium chloride, hydrogen, hydrogen chloride, and argon may be continuously supplied, and the RF power supply may continuously supply RF power. As illustrated in FIG. 4, in step S16, zirconium chloride, hydrogen, hydrogen chloride, and argon may be supplied continuously, and the RF power supply may be supplied in a pulse form. Step S16 may include adjusting a ratio of a film formation rate of the zirconium film 150 formed on the bottom surface 131 to a film formation rate of the zirconium film 150 formed on the side surface 132 and the upper surface 133 by changing a timing of switching the RF power between on and off.

Step S16 may include adjusting a ratio of a film formation rate of the zirconium film 150 formed on the bottom surface 131 to a film formation rate of the zirconium film 150 formed on the side surface 132 and the upper surface 133 by changing a flow rate ratio between zirconium chloride and hydrogen chloride.

Step S16 may be performed after step S14, without exposing the substrate 100 to the air atmosphere. In this case, the zirconium film 150 can be formed on the surfaces of the recess 130 in a state where the native oxide film 140 is not present on the surfaces of the recess 130.

The condition of step S16 is, for example, as follows:
Processing volume: 20 liters or more and 22 liters or less
RF power: Continuous wave of 100 W or more and 1000 W or less
Pressure: 267 Pa or more and 1200 Pa or less (2 Torr or more and 9 Torr or less)
Substrate temperature: 350° C. or more and 500° C. or less
Zirconium chloride: 1 sccm or more and 30 sccm or less
Hydrogen: 10 sccm or more and 4000 sccm or less
Hydrogen chloride: 5 sccm or more and 200 sccm or less
Argon: 1200 sccm or more and 2400 sccm or less

Step S18 includes filling the recess 130 with a ruthenium film 160, as illustrated in FIG. 2D. Ruthenium (Ru) is an example of a second metal, and the ruthenium film 160 is an example of a second film. Step S18 includes supplying a ruthenium-containing raw material gas and carbon monoxide (CO) to the substrate 100 to fill the recess 130 with the ruthenium film 160. The raw material gas containing ruthenium is, for example, Ru₃(CO)₁₂. Step S18 may include maintaining the substrate 100 at a temperature of 160° C. or more and 180° C. or less.

Step S18 may be performed without exposing the substrate 100 to the air atmosphere after step S16. In this case, the surface of the zirconium film 150 can be prevented from being oxidized before the ruthenium film 160 is formed on the zirconium film 150. Therefore, an increase in electric resistance due to oxidation of the zirconium film 150 can be prevented. For example, the formation of the zirconium film 150 and the filling with the ruthenium film 160 are performed in different chambers, and the substrate 100 is vacuum-transported between after the formation of the zirconium film 150 and before the filling with the ruthenium film 160. In this case, in order to further prevent oxidation of the surface of the zirconium film 150, the surface of the zirconium film 150 may be nitrided in the chamber for forming the zirconium film 150.

According to the film forming method of the first embodiment, zirconium chloride and hydrogen chloride are simultaneously supplied to the substrate 100 to form the zirconium film 150 on the surfaces of the recess 130. In this case, the zirconium film 150 can be formed on the bottom surface 131 of the recess 130 to be thicker than on the side surface 132 and the upper surface 133. Therefore, the volume of the ruthenium film 160 filling the recess 130 can be increased while the contact resistance between the silicon substrate 110 and the ruthenium film 160 is reduced by the zirconium film 150 formed on the bottom surface 131. Therefore, in the case where the ruthenium film 160 is used as an interconnect layer, the interconnect resistance can be reduced.

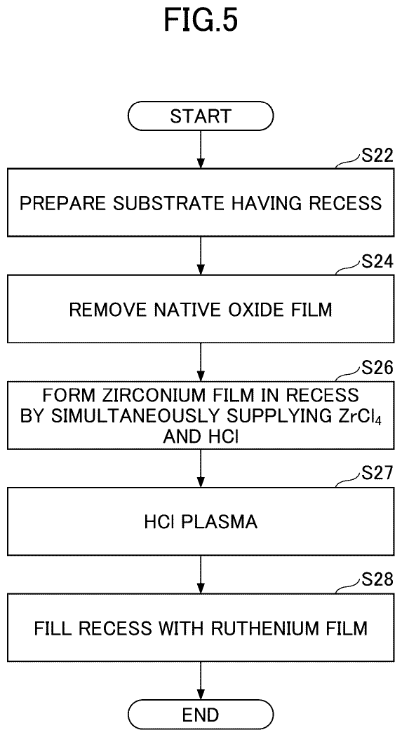

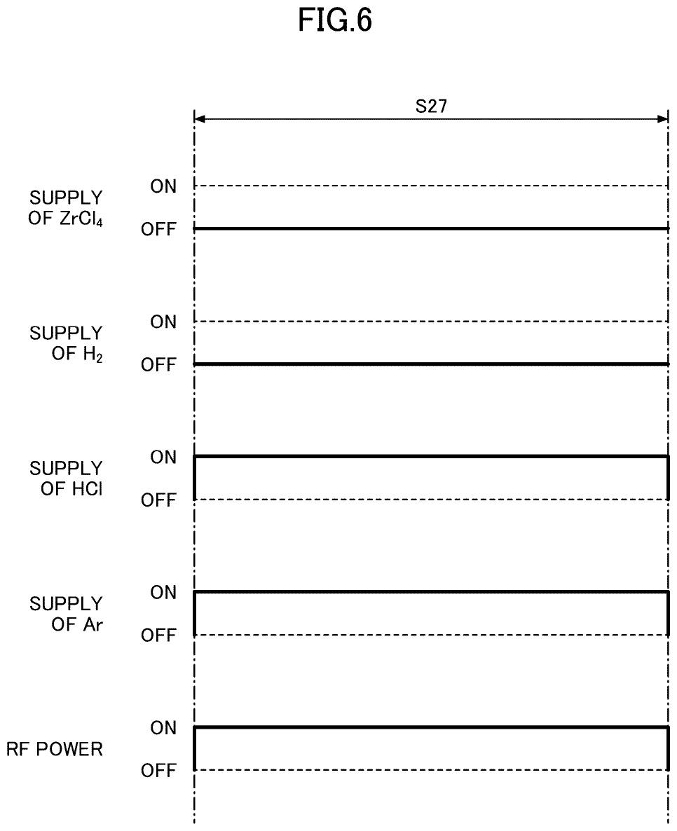

A film forming method according to the second embodiment will be described with reference to FIGS. 5 and 6. FIG. 5 is a flowchart illustrating a film forming method according to the second embodiment. FIG. 6 is a timing chart illustrating an example of step S27 in FIG. 5. The film forming method according to the second embodiment includes step S22, step S24, step S26, step S27, and step S28 illustrated in FIG. 5.

Step S22, step S24, step S26, and step S28 are the same as step S12, step S14, step S16, and step S18, respectively.

Step S27 is performed between step S26 and step S28. Step S27 includes supplying plasma generated from hydrogen chloride (hereinafter referred to as “hydrogen chloride plasma”), without supplying zirconium chloride to the substrate 100. In this case, the zirconium film 150 remaining on the side surface 132 and the upper surface 133 after step S26 can be removed by etching. An RF power supply may be used to generate plasma. Step S27 may include providing an inert gas such as argon. As illustrated in FIG. 6, in step S27, hydrogen chloride and argon may be continuously supplied without a supply of zirconium chloride and hydrogen, and the RF power supply may continuously supply RF power.

The condition of step S27 is, for example, as follows:
Processing volume: 20 liters or more and 22 liters or less
RF power: Continuous wave of 100 W or more and 1000 W or less
Pressure: 267 Pa or more and 1200 Pa or less (2 Torr or more and 9 Torr or less)
Substrate temperature: 350° C. or more and 500° C. or less
Zirconium chloride: 0 sccm
Hydrogen: 0 sccm
Hydrogen chloride: 5 sccm or more and 200 sccm or less
Argon: 1200 sccm or more and 2400 sccm or less

According to the film forming method of the second embodiment, zirconium chloride and hydrogen chloride are simultaneously supplied to the substrate 100 to form the zirconium film 150 on the surfaces of the recess 130. In this case, the zirconium film 150 can be formed on the bottom surface 131 of the recess 130 to be thicker than on the side surface 132 and the upper surface 133. Therefore, the volume of the ruthenium film 160 filling the recess 130 can be increased while the contact resistance between the silicon substrate 110 and the ruthenium film 160 is reduced by the zirconium film 150 formed on the bottom surface 131. As a result, the interconnect resistance can be reduced in the case where the ruthenium film 160 is used as an interconnect layer.

According to the film forming method of the second embodiment, the zirconium film 150 is formed in step S26, then hydrogen chloride plasma is supplied to the substrate 100 in step S27, and then the ruthenium film 160 fills the recess 130 in step S28. In this case, the recess 130 is filled with the ruthenium film 160 in a state where the zirconium film 150 is not present or hardly present on the side surface 132 of the recess 130. Therefore, the volume of the ruthenium film 160 filling the recess 130 can be increased. As a result, the interconnect resistance can be reduced particularly in the case where the ruthenium film 160 is used as an interconnect layer.

### <Processing System>

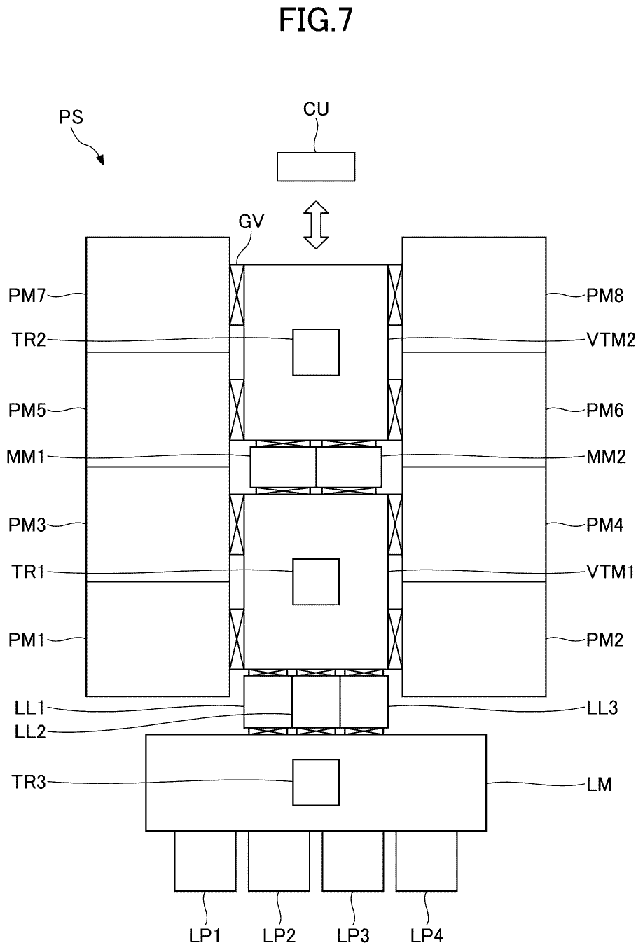

A processing system PS according to an embodiment will be described with reference to FIG. 7. FIG. 7 is a diagram illustrating a processing system according to the embodiment.

The processing system PS includes processing apparatuses PM1 through PM8, vacuum transport chambers VTM1 and VTM2, intermediate transport chambers MM1 and MM2, load lock chambers LL1 through LL3, an atmospheric transport chamber LM, load ports LP1 through LP4, and an overall control unit CU.

The processing apparatuses PM1 through PM4 are connected to the vacuum transport chamber VTM1. The inside of each of the processing apparatuses PM1 through PM4 is depressurized to a vacuum atmosphere. The processing apparatuses PM1 through PM4 perform a desired process on a substrate inside respective processing apparatuses PM1 through PM4. The processing apparatuses PM1 and PM2 are apparatuses that perform step S14 and step S24 described above, for example. The processing apparatuses PM3 and PM4 are apparatuses that perform step S16, step S26, and step S27 described above, for example.

The processing apparatuses PM5 through PM8 are connected to the vacuum transport chamber VTM2. The inside of each of the processing apparatuses PM5 through PM8 is depressurized to a vacuum atmosphere. The processing apparatuses PM5 through PM8 perform a desired process on a substrate inside respective processing apparatuses PM5 through PM8. The processing apparatuses PM5 through PM8 are apparatuses that perform step S18 and step S28 described above, for example.

The inside of the vacuum transport chamber VTM1 is depressurized to a vacuum atmosphere. A transport mechanism TR1 is provided inside the vacuum transport chamber VTM1. The transport mechanism TR1 is configured to be capable of transporting a substrate in a depressurized state. The transport mechanism TR1 transports a substrate between the processing apparatuses PM1 through PM4, the intermediate transport chambers MM1 and MM2, and the load lock chambers LL1 through LL3.

The inside of the vacuum transport chamber VTM2 is depressurized to a vacuum atmosphere. A transport mechanism TR2 is provided inside the vacuum transport chamber VTM2. The transport mechanism TR2 is configured to be capable of transporting a substrate in a depressurized state. The transport mechanism TR2 transports a substrate between the processing apparatuses PM5 through PM8 and the intermediate transport chambers MM1 and MM2.

The intermediate transport chamber MM1 and the MM2 are provided between the vacuum transport chamber VTM1 and the vacuum transport chamber VTM2. The intermediate transport chambers MM1 and MM2 are connected to the vacuum transport chamber VTM1 and are connected to the vacuum transport chamber VTM2. The inside of the intermediate transport chambers MM1 and MM2 is depressurized to a vacuum atmosphere. The intermediate transport chambers MM1 and MM2 may have a cooling mechanism that cools a substrate.

The load lock chambers LL1 and LL3 are provided between the vacuum transport chamber VTM1 and the atmospheric transport chamber LM. The load lock chambers LL1 and LL3 are connected to the vacuum transport chamber VTM1 and are connected to the atmospheric transport chamber LM. The inside of the load lock chambers LL1 through LL3 can be switched between an air atmosphere and a vacuum atmosphere. The load lock chambers LL1 through LL3 may have a cooling mechanism that cools a substrate, similarly to the intermediate transport chambers MM1 and MM2.

The inside of the atmospheric transport chamber LM is in an atmospheric atmosphere. A downflow of clean air is formed inside the atmospheric transport chamber LM, for example. A transport mechanism TR3 is provided in the atmospheric transport chamber LM. The transport mechanism TR3 transports substrates between the load lock chambers LL1 through LL3 and the carriers placed at the load ports LP1 through LP4.

The load ports LP1 through LP4 are provided on the wall of the long sides of the atmospheric transport chamber LM. A carrier is placed at each of the load ports LP1 through LP4. The carrier is, for example, a front opening unified pod (FOUP).

Gate valves GV are provided between the processing apparatuses PM1 through PM4 and the vacuum transport chamber VTM1, between the processing apparatuses PM5 through PM8 and the vacuum transport chamber VTM2, between the vacuum transport chamber VTM1 and the intermediate transport chambers MM1 and MM2, between the vacuum transport chamber VTM2 and the intermediate transport chambers MM1 and MM2, between the load lock chambers LL1 through LL3 and the vacuum transport chamber VTM1, and between the load lock chambers LL1 through LL3 and the atmospheric transport chamber LM, respectively.

The overall control unit CU is an electronic circuit such as a central processing unit (CPU), a field programmable gate array (FPGA), or an application specific integrated circuit (ASIC). The overall control unit CU performs various control operations described in the present specification by executing instruction codes stored in a memory or by including a circuit designed for a special purpose. For example, the overall control unit CU controls the operation of the processing apparatuses PM1 through PM8, the operation of the transport mechanisms TR1 through TR3, the switching of the atmosphere in the load lock chambers LL1 through LL3, the opening and closing of the gate valves GV, and the like.

### <Operation of Processing System>

An example of the operation of the processing system PS according to the embodiment will be described with reference to FIG. 7. Hereinafter, a case where the processing system PS performs the film forming method illustrated in FIG. 1 will be described as an example. The operation of the processing system PS according to the embodiment is performed under the control of the overall control unit CU. Hereinafter, the description regarding the opening and closing of the gate valve GV will be omitted.

First, a transport device provided outside the processing system PS loads a carrier into the load port LP1. The transport device is, for example, an overhead hoist transport (OHT). An operator may load a carrier into the load port LP1. The carrier accommodates the substrate 100 described above.

Next, the transport mechanism TR3 transports the substrate 100 accommodated in the carrier to the load lock chamber LL1 in the air atmosphere. Subsequently, the inside of the load lock chamber LL1 is switched from the atmospheric atmosphere to the vacuum atmosphere.

Next, the transport mechanism TR1 receives the substrate 100 from the load lock chamber LL1 and transports the substrate 100 to the processing apparatus PM1. Subsequently, the processing apparatus PM1 performs step S14. In other words, the processing apparatus PM1 removes the native oxide film 140.

Next, the transport mechanism TR1 receives the substrate 100 from the processing apparatus PM1 and transports the substrate 100 to the processing apparatus PM3. Subsequently, the processing apparatus PM3 performs step S16. In other words, the processing apparatus PM3 simultaneously supplies zirconium chloride, hydrogen, and hydrogen chloride to the substrate 100 to form the zirconium film 150 on the surfaces of the recess 130. In this case, the supply of zirconium chloride as a raw material gas and the supply of hydrogen chloride as an etching gas can be performed simultaneously in the same processing apparatus PM3, and thus the processing time can be shortened.

Next, the transport mechanism TR1 receives the substrate 100 from the processing apparatus PM3 and transports the substrate 100 to the intermediate transport chamber MM1. Subsequently, the intermediate transport chamber MM1 cools the substrate 100 with the cooling mechanism.

Next, the transport mechanism TR2 receives the substrate 100 from the intermediate transport chamber MM1 and transports the substrate 100 to the processing apparatus PM5. Subsequently, the processing apparatus PM5 performs step S18. In other words, the processing apparatus PM5 fills the recess 130 with the ruthenium film 160. The temperature at which the processing apparatus PM5 performs step S18 is lower than the temperature at which the processing apparatus PM3 performs step S16. The substrate 100 cooled in the intermediate transport chamber MM1 is transported to the processing apparatus PM5. In this case, a temperature variation caused by the substrate 100 being carried into the processing apparatus PM5 can be reduced. Therefore, the ruthenium film 160 can be stably formed in the processing apparatus PM5.

Next, the transport mechanism TR2 receives the substrate 100 from the processing apparatus PM5 and transports the substrate 100 to the intermediate transport chamber MM2. Subsequently, the intermediate transport chamber MM2 cools the substrate 100 by the cooling mechanism.

Next, the transport mechanism TR1 receives the substrate 100 from the intermediate transport chamber MM2 and transports the substrate 100 to the load lock chamber LL2. Subsequently, the inside of the load lock chamber LL2 is switched from the vacuum atmosphere to the atmospheric atmosphere.

Next, the transport mechanism TR3 receives the substrate 100 from the load lock chamber LL2, transports the substrate 100 to the carrier placed at the load port LP2, and accommodates the substrate 100 in the carrier. Thus, the processing for one substrate 100 is completed.

The transport path of the substrate 100 in the operation of the processing system PS described above is an example, and the transport path of the substrate 100 is not limited thereto.

### <Film Forming Apparatus>

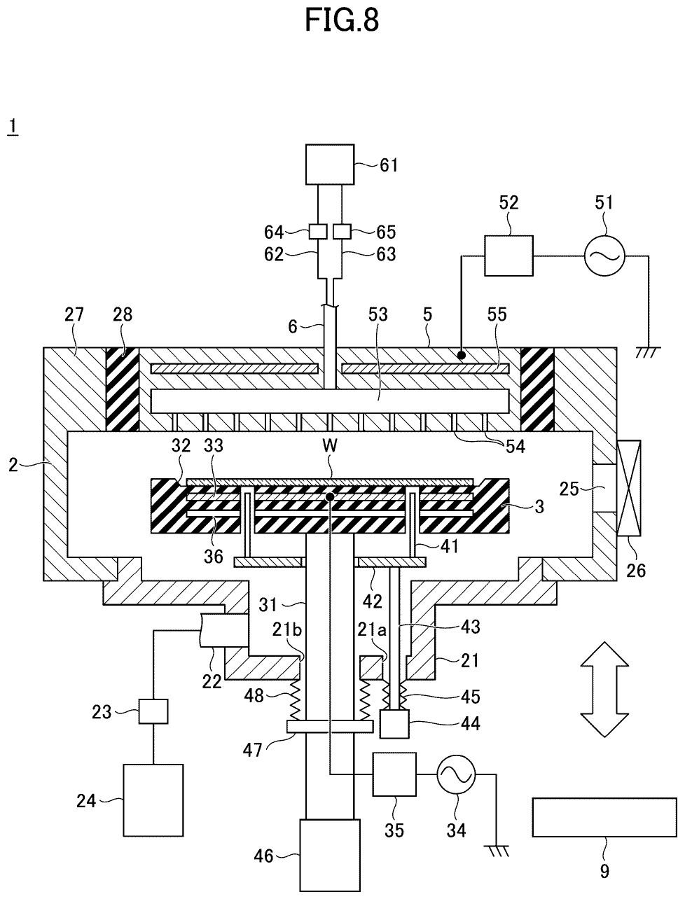

A film forming apparatus 1, which is an example of the processing apparatus PM3 included in the processing system PS, will be described with reference to FIG. 8. FIG. 8 is a cross-sectional view illustrating the film forming apparatus 1 according to the embodiment. The processing apparatus PM4 may have a configuration similar to that of the processing apparatus PM3. The processing apparatuses PM1, PM2, and PM4 through PM8 may have the same configuration as the processing apparatuses PM3 except for the type of gas.

The film forming apparatus 1 includes a processing chamber 2. The processing chamber 2 accommodates a substrate W. The substrate W may be the substrate 100 described above. The processing chamber 2 has a substantially cylindrical shape. The processing chamber 2 is a vacuum container capable of reducing the pressure of the vacuum container. An exhaust chamber 21 is provided in a central portion of a bottom wall of the processing chamber 2.

The exhaust chamber 21 has a substantially cylindrical shape protruding downward. An exhaust flow path 22 is connected to a side surface of the exhaust chamber 21. An exhauster 24 is connected to the exhaust flow path 22 via a pressure adjuster 23. The pressure adjuster 23 includes a pressure adjusting valve such as a butterfly valve. The pressure adjuster 23 adjusts the pressure in the processing chamber 2. The exhauster 24 includes a vacuum pump. The exhauster 24 depressurizes the inside of the processing chamber 2 through the exhaust flow path 22. A transport port 25 is provided in a side surface of the processing chamber 2. The transport port 25 is an opening through which the substrate W passes when the substrate W is carried into the processing chamber 2 and when the substrate W is carried out from the processing chamber 2. The transport port 25 is opened and closed by a gate valve 26.

A placement table 3 is provided in the processing chamber 2. The placement table 3 holds the substrate W horizontally. The placement table 3 has a substantially circular shape in plan view. The placement table 3 is supported by a support member 31. A recess 32 is provided in the surface of the placement table 3. The recess 32 has a substantially circular shape in plan view. The substrate W is placed in the recess 32. The recess 32 has an inner diameter slightly larger than the diameter of the substrate W. The recess 32 has a depth substantially equal to the thickness of the substrate W. The placement table 3 is formed of, for example, a ceramic material such as aluminum nitride (AlN). The placement table 3 may be formed of a metal material such as nickel (Ni). Instead of the recess 32, an annular guide member for guiding the peripheral portion of the substrate W may be provided on the surface of the placement table 3.

A lower electrode 33 is provided inside the placement table 3. An RF power supply 34 is connected to the lower electrode 33. The RF power supply 34 supplies a first RF (radio frequency) power to the lower electrode 33. The first RF power is a bias RF power for attracting ions to the substrate W. The first RF power has a frequency within a range of, for example, 100 kHz or more and 60 MHz or less. A matcher 35 is provided between the lower electrode 33 and the RF power supply 34. A DC (direct current) power supply may be connected to the lower electrode 33. The DC power supply supplies a DC power for bias or a pulse DC power to the lower electrode 33. The lower electrode 33 may be grounded. In the case where the entire placement table 3 is formed of a metal, the entire placement table 3 functions as the lower electrode. Therefore, the lower electrode 33 may not be provided inside the placement table 3.

A temperature control mechanism 36 is provided inside the placement table 3. The temperature control mechanism 36 is located below the lower electrode 33. The temperature adjustment mechanism 36 adjusts the temperature of the substrate W placed in the recess 32 to a set temperature based on a control signal from the controller 9. The temperature adjustment mechanism 36 includes, for example, a heater. The temperature control mechanism 36 may include a fluid flow path through which a temperature control fluid flows.

A plurality of (e.g., three) lifting pins 41 are provided in the placement table 3. The plurality of lifting pins 41 hold and lift up and down the substrate W placed in the recess 32. Each of the lifting pins 41 is formed of a ceramic such as alumina (Al₂O₃). Each of the lifting pins 41 may be formed of quartz. The lower ends of the lifting pins 41 are attached to a support plate 42. The support plate 42 is connected to a lifting mechanism 44 provided outside the processing chamber 2 via a lifting shaft 43.

The lifting mechanism 44 is provided below the exhaust chamber 21. A bellows 45 is provided between the lifting mechanism 44 and an opening 21a for the lifting shaft 43 formed in the lower surface of the exhaust chamber 21. The support plate 42 has a shape that can be lifted up and down without touching the support member 31 of the placement table 3. The lifting mechanism 44 lifts up the upper end of the lifting pin 41 between a position above the bottom surface of the recess 32 and a position below the bottom surface of the recess 32. Thus, the substrate W is lifted up and down between a position where the substrate W is placed on the bottom surface of the recess 32 (the position illustrated in FIG. 6) and a position (not illustrated) away from the bottom surface of the recess 32.

The lower end of the support member 31 penetrates an opening 21b of the exhaust chamber 21. A lower end of the support member 31 is supported by a lifting mechanism 46 via a lifting plate 47 provided below the processing chamber 2. A bellows 48 is provided between the bottom of the exhaust chamber 21 and the lifting plate 47. Accordingly, the airtightness in the processing chamber 2 is maintained even by a vertical movement of the lifting plate 47.

The lifting mechanism 46 lifts up the placement table 3 by lifting up the lifting plate 47. Accordingly, the gap between the placement table 3 and the gas supplier 5 can be adjusted.

The gas supplier 5 is provided on the ceiling wall 27 of the processing chamber 2 via the insulating member 28. The gas supplier 5 functions as an upper electrode. The gas supplier 5 faces the lower electrode 33. An RF power supply 51 is connected to the gas supplier 5. The RF power supply 51 supplies a second RF power to the gas supplier 5. The second RF power is an RF power for plasma generation necessary for forming a film on the substrate W. The second RF power has a frequency within a range of, for example, 100 kHz or more and 150 MHz or less. A matcher 52 is provided between the gas supplier 5 and the RF power supply 51. When the RF power is supplied from the RF power supply 51 to the gas supplier 5, an RF electric field is generated between the gas supplier 5 (upper electrode) and the lower electrode 33.

The gas supplier 5 has a gas diffusion chamber 53. The gas diffusion chamber 53 has a hollow shape. A plurality of holes 54 for dispersedly supplying a processing gas into the processing chamber 2 are formed in a lower surface of the gas diffusion chamber 53, for example, at regular intervals. A heating mechanism 55 is embedded above the gas diffusion chamber 53 in the gas supplier 5. The heating mechanism 55 includes, for example, a heater. The heating mechanism 55 heats the gas supplier 5 to a set temperature based on a control signal from the controller 9.

A gas supply path 6 communicates with the gas diffusion chamber 53. A gas source 61 is connected to an upstream side of the gas supply path 6 via a first gas line 62 and a second gas line 63. The gas source 61 includes supply sources of various processing gases, mass flow controllers, and valves.

The first gas line 62 connects the gas source 61 and the gas supply path 6. A first temperature adjuster 64 is provided at a location partway along the first gas line 62. The first temperature adjuster 64 adjusts the temperature of a processing gas flowing through the first gas line 62. The first temperature adjuster 64 includes, for example, a heater.

The second gas line 63 connects the gas source 61 and the gas supply path 6. A second temperature adjuster 65 is provided at a location partway along the second gas line 63. The second temperature adjuster 65 adjusts the temperature of a processing gas flowing through the second gas line 63. The second temperature adjuster 65 includes, for example, a heater.

Through the provision of the first gas line 62, the second gas line 63, the first temperature adjuster 64, and the second temperature adjuster 65, the processing gas can be introduced into the gas diffusion chamber 53 at an appropriate temperature according to the type of the processing gas.

The various processing gases include processing gases used in the film forming methods according to the first embodiment and the second embodiment. The various processing gases include, for example, zirconium chloride, hydrogen, hydrogen chloride, and argon. Zirconium chloride, hydrogen, and argon are introduced into the gas diffusion chamber 53 from, for example, the gas source 61 through the first gas line 62. Zirconium chloride has a low vapor pressure. Therefore, the first temperature adjuster 64 adjusts the temperature of zirconium chloride flowing through the first gas line 62 to a first temperature at which the zirconium chloride is vaporized. The first temperature is, for example, 190° C. or greater. Hydrogen chloride is introduced into the gas diffusion chamber 53 from the gas source 61 through the second gas line 63. When the temperature of hydrogen chloride becomes high, the hydrogen chloride may corrode a member or the like constituting the second gas line 63. Therefore, the second temperature adjuster 65 adjusts the temperature of the hydrogen chloride flowing through the second gas line 63 to the second temperature lower than the first temperature. The second temperature is, for example, 100° C. or less.

The film forming apparatus 1 includes the controller 9. The controller 9 is an electronic circuit such as a central processing unit (CPU), a field programmable gate array (FPGA), or an application specific integrated circuit (ASIC). The controller 9 performs various control operations described in the present specification by executing instruction codes stored in a memory or by including a circuit designed for a special purpose.

### <Experimental Results>

First, a silicon substrate and a silicon nitride substrate were prepared. Subsequently, in the above-described film forming apparatus 1, a zirconium film was formed on each of the prepared silicon substrate and silicon nitride substrate under the following conditions A and B. Subsequently, the thickness of the zirconium film formed on each substrate was measured.

### (Condition A)

RF power: Continuous wave of 300 W
Pressure: 800 Pa (6 Torr)
Substrate temperature: 450° C.
Zirconium chloride: 1 sccm
Hydrogen: 4000 sccm
Hydrogen chloride: 0 sccm
Argon: 2400 sccm
Time: 180 seconds

### (Condition B)

RF power: Continuous wave of 300 W
Pressure: 800 Pa (6 Torr)
Substrate temperature: 450° C.
Zirconium chloride: 1 sccm
Hydrogen: 4000 sccm
Hydrogen chloride: 50 sccm
Argon: 2400 sccm
Time: 180 seconds

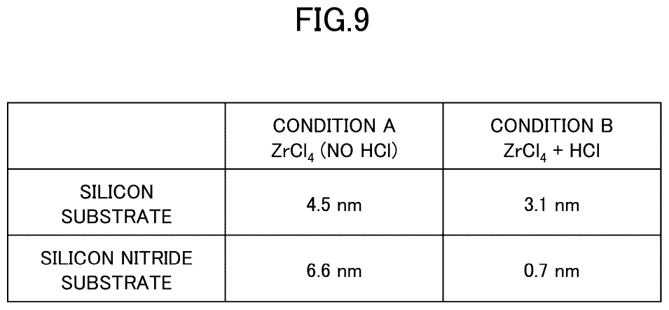

FIG. 9 is a diagram showing the results of measuring a thickness of a zirconium film. In FIG. 9, the values in the upper row show the thickness of the zirconium film formed on the silicon substrate, and the values in the lower row show the thickness of the zirconium film formed on the silicon nitride substrate. In FIG. 9, the values in the left column show the thickness of the zirconium film formed under the condition A, and the values in the right column show the thickness of the zirconium film formed under the condition B.

As shown in FIG. 9, the thickness of the zirconium film formed on the silicon substrate under the condition A was 4.5 nanometers (nm), and the thickness of the zirconium film formed on the silicon nitride substrate under the condition A was 6.6 nm. The thickness of the zirconium film formed on the silicon substrate under the condition B was 3.1 nm, and the thickness of the zirconium film formed on the silicon nitride substrate under the condition B was 0.7 nm. These results show that a zirconium film can be formed on a silicon substrate to be thicker than on a silicon nitride film by simultaneously supplying zirconium chloride and hydrogen chloride.

The embodiments disclosed herein are merely an example in all respects and should not be construed as being limited thereto. The above-described embodiments may be omitted, replaced, and modified in various forms without departing from the scope and spirit of the appended claims.

In the foregoing embodiments, the case where the recess including the bottom surface and the side surface is formed on the surface of the substrate, the semiconductor film including silicon forms the bottom surface, and the insulating film forms the side surface has been described, but the present disclosure is not limited thereto. The substrate may have a semiconductor film containing silicon and an insulating film on its surface, and a recess is not necessarily formed on the surface of the substrate.

In the foregoing embodiments, the case where the semiconductor region is a silicon substrate has been described, but the present disclosure is not limited thereto. The semiconductor region may be a germanium substrate or a silicon germanium substrate. The semiconductor region may be a substrate having a film containing silicon such as a silicon film, a germanium film, or a silicon germanium film formed on the surface of the semiconductor region.

In the foregoing embodiments, the case where the insulator region is a silicon nitride film has been described, but the present disclosure is not limited thereto. The insulator region may be a silicon oxide film.

In the foregoing embodiments, the case where the raw material gas is zirconium chloride has been described, but the present disclosure is not limited thereto. The raw material gas may be a metal chloride. The raw material gas may be titanium chloride (TiCl₄), tungsten chloride (WCl₅), molybdenum chloride (MoCl₅), or hafnium chloride (HfCl₄).

In the foregoing embodiments, the case where the etching gas is hydrogen chloride has been described, but the present disclosure is not limited thereto. The etching gas may be a gas containing chlorine. The etching gas may be chlorine (Cl₂).

In the foregoing embodiments, the case where the film forming apparatus is an apparatus using capacitively coupled plasma (CCP) has been described, but the present disclosure is not limited thereto. For example, the film forming apparatus may be an apparatus using inductively coupled plasma (ICP) or microwave discharge plasma.

In the foregoing embodiments, the case where the film forming apparatus is a single wafer type apparatus that processes substrates one by one has been described, but the present disclosure is not limited thereto. For example, the film forming apparatus may be a batch-type apparatus that processes a plurality of substrates at a time.

What is claimed is:

1. A metal-containing film forming method, comprising:
preparing a substrate having a semiconductor region containing silicon and an insulator region on a surface of the substrate; and
forming a first film containing a first metal on the surface of the substrate by simultaneously supplying a raw material gas containing the first metal and an etching gas for etching the first film to the substrate.

2. The film forming method according to claim 1, wherein
the forming the first film includes generating plasma from the raw material gas and the etching gas.

3. The film forming method according to claim 1, wherein
the forming the first film includes forming a metal silicide from the silicon included in the semiconductor region and the first metal included in the raw material gas.

4. The film forming method according to claim 1, wherein
the forming the first film includes forming the first film on the semiconductor region to be thicker than on the insulator region.

5. The film forming method according to claim 1, wherein
the forming the first film includes adjusting a ratio of a film formation rate of the first film formed on the semiconductor region to a film formation rate of the first film formed on the insulator region by changing a flow rate ratio between the raw material gas and the etching gas.

6. The film forming method according to claim 2, wherein
the forming the first film includes adjusting a ratio of a film formation rate of the first film formed on the semiconductor region to a film formation rate of the first film formed on the insulator region by changing timing of switching an RF power supply used for generating the plasma between on and off.

7. The film forming method according to claim 1, further comprising supplying, after the forming of the first film, plasma generated from the etching gas to the substrate without supplying the raw material gas to the substrate.

8. The film forming method according to claim 1, wherein
a recess including a bottom surface and a side surface is formed on the surface of the substrate,
the semiconductor region forms the bottom surface, and
the insulator region forms the side surface.

9. The film forming method according to claim 8, further comprising filling the recess with a second film containing a second metal after the forming the first film.

10. The film forming method according to claim 9, wherein
the filling the recess is performed after the forming the first film, without exposing the substrate to an air atmosphere.

11. The film forming method according to claim 1, further comprising removing a native oxide film on the surface of the substrate before the forming the first film.

12. The film forming method according to claim 11, wherein
the forming the first film is performed after removing the native oxide film, without exposing the substrate to an air atmosphere.

13. The film forming method according to claim 1, wherein
the raw material gas is a metal chloride, and
the etching gas is a gas containing chlorine.

14. The film forming method according to claim 13, wherein
the metal chloride is zirconium chloride, and
the gas containing chlorine is hydrogen chloride.

15. The film forming method according to claim 1, wherein
the insulator region is a silicon nitride film or a silicon oxide film.

16. A metal-containing film forming apparatus, comprising:
a processing chamber;
a gas supplier configured to supply a gas into the processing chamber; and
a controller, wherein
the controller is configured to perform
preparing a substrate having a semiconductor region containing silicon and an insulator region on a surface of the substrate; and
forming a first film containing a first metal on the surface of the substrate by simultaneously supplying a raw material gas containing the first metal and an etching gas for etching the first film to the substrate.
